(19) United States
(12) Patent Application Publication
(10) Pub. No.: US 2025/0380559 A1
(43) Pub. Date: Dec. 11, 2025

(54) LIGHT EMITTING DIODE LAMP PANEL AND BACKLIGHT MODULE

(71) Applicant: Shenzhen Refond Optoelectronics Co., Ltd, Shenzhen (CN)

(72) Inventors: Ji Wu, Shenzhen (CN); Longxiang Lin, Shenzhen (CN); Weibin Gong, Shenzhen (CN); Juan Liu, Shenzhen (CN)

(21) Appl. No.: 19/231,332

(22) Filed: Jun. 6, 2025

(30) Foreign Application Priority Data
Jun. 6, 2024 (CN) 202421292801.5

(51) Int. Cl. H10H 29/856

(52) U.S. Cl. CPC H10H 29/856

(57) ABSTRACT

The present disclosure relates to the technical field of display devices, and in particular to a light emitting diode (LED) lamp panel and a backlight module. The LED lamp panel includes a base plate, light-emitting chips are electrically connected to the base plate, the light-emitting chips are wrapped with sealant layers, and corresponding optical lens structures are arranged between the light-emitting chips. Within the optical lens structures, light rays undergo optical processing including refraction, reflection, total internal reflection, etc., and the light rays emitted laterally from the light-emitting chips are redirected by the optical lens structures, being reflected toward a region above the base plate to achieve uniform light mixing.

### CROSS-REFERENCE TO RELATED APPLICATION

This application claims priority of Chinese Patent Application No. 202421292801.5, filed on Jun. 6, 2024 the entire contents of which are incorporated herein by reference.

### TECHNICAL FIELD

The present disclosure relates to the technical field of display devices, and in particular to a light emitting diode (LED) lamp panel and a backlight module.

### BACKGROUND

Development directions in the technical field of display devices are moving toward thinner, lighter, and more cost-effective products in response to shifting consumer demands and technological advancements. Amid this trend, enterprises across the photoelectronic industry are exploring optimal product design directions and manufacturing approaches. One primary approach involves confining an optical mixing distance within a reduced range, thereby achieving thinner product designs. However, as the optical mixing distance decreases, dark zones or bright spots tend to be formed at an intersection center of four LEDs due to a rectangular array arrangement of lamp panels being combined with circular halos of individual LED emissions. Concurrently, there are variations in row and column spacing within the rectangular array arrangement of LED, thereby resulting in brighter or darker zones being observed along horizontal and vertical directions, ultimately leading to compromised visual performance characterized by poor luminance uniformity or color inconsistency across the LED lamp panel.

### SUMMARY

The present disclosure provides an LED lamp panel and a backlight module to solve the problem of uneven light mixing of existing LEDs.

A solution of the present disclosure is to provide an LED lamp panel for solving technical problems. A base plate is included, light-emitting chips are electrically connected to the base plate, the light-emitting chips are wrapped with sealant layers, corresponding optical lens structures are arranged between the light-emitting chips, a concave pit is arranged on one face of each optical lens structure away from the base plate, and an enclosure is formed around the concave pit.

Preferably, a ratio of a bottom height of the concave pit to a diameter of the optical lens structure is less than or equal to 0.6, and a ratio of a maximum height of the enclosure to the diameter of the optical lens structure is less than or equal to 0.8.

Preferably, a reflecting layer is arranged on the base plate, and the optical lens structures and the light-emitting chips are arranged on the reflecting layer.

Preferably, position avoidance holes corresponding to the light-emitting chips are disposed on the reflecting layer.

Preferably, the light-emitting chips are arranged in an array on the base plate, and the optical lens structures are arranged at centers of a plurality of light-emitting chips.

Preferably, the optical lens structures are distributed in dot, line or mesh patterns.

Preferably, gaps are arranged between the optical lens structures and the sealant layers.

Preferably, a ratio of the diameter of the optical lens structure to a distance between the two light-emitting chips is greater than or equal to 0.1.

Preferably, the light-emitting chips may emit monochromatic light or polychromatic light.

The present disclosure further provides a backlight module, and the backlight module includes the above LED lamp panel.

Compared to the related art, the LED lamp panel and the backlight module provided by the present disclosure have the following advantages.

1. According to the LED lamp panel provided in an embodiment of the present disclosure, the optical lens structures are arranged on the base plate corresponding to the light-emitting chips. Within the optical lens structures, light rays undergo optical processing including refraction, reflection, total internal reflection, etc. The concave pit is arranged on one face of each optical lens structure away from the base plate, and an enclosure is formed around the concave pit, and an enclosure is formed around the concave pit, to cause the light rays to undergo multiple reflections and refractions when passing through the optical lens structures, thereby achieving more uniform coverage across the entire emission area, mitigating observable light spots or non-uniformity, enhancing utilization efficiency of the light-emitting chips, and reducing optical energy loss. Moreover, a reasonably designed optical lens structure can compensate for light rays directed toward one side of the base plate, ensuring more uniform illumination distribution across targeted light areas while enhancing visual performance and ocular comfort.

2. According to the LED lamp panel provided in an embodiment of the present disclosure, the reflecting layer can effectively redirect the lights emitted from the light-emitting chips and the optical lens structures toward an exterior of the base plate, thereby enhancing the overall light output quality of the lamp panel.

3. According to the LED lamp panel provided in an embodiment of the present disclosure, the light-emitting chips are arranged in an array on the base plate, and the optical lens structures are arranged between or around the light-emitting chips. The light rays passing through these optical lens structures are more effectively controlled and directed, facilitating efficient focusing, scattering, or reflection of the emitted light rays from the light-emitting chips.

4. According to the LED lamp panel provided in an embodiment of the present disclosure, various optical lens structure distribution patterns such as dot, line or mesh patterns exhibit distinct advantages in LED lamp panels under different emission conditions. Dot-patterned optical lens structures are suitable for use at an intersection center of four lamps, ensuring precise control over light direction. Line-patterned optical lens structures are optimally implemented on LED lamp panels exhibiting stripe-pattern luminance variations. Mesh-patterned optical lens structures can integrate the advantages of both dot and line patterns, ensuring precise control over light directionality and intensity, while facilitating light diffusion and uniform distribution.

5. According to the LED lamp panel provided in an embodiment of the present disclosure, the gaps can provide passages for heat transfer, facilitating the effective dissipation of heat generated by the light-emitting chips into the ambient environment, minimizing direct contact between the optical lens structures and the sealant layers, thereby preventing potential the optical lens structures from being affected by the sealant layers.

6. According to the LED lamp panel provided in an embodiment of the present disclosure, as the distance between the light-emitting chips increases, the diameter of the optical lens structure proportionally enlarges, which enhances optical efficiency by capturing more lateral light rays, thereby expanding illumination coverage while mitigating uneven lighting distribution or optical failures between the optical lens structure and the light-emitting chip.

7. The backlight module provided in an embodiment of the present disclosure has the same beneficial effects as the above LED lamp panel.

### BRIEF DESCRIPTION OF THE DRAWINGS

To more clearly illustrate the technical solutions in embodiments of the present disclosure, the accompanying drawings required for use in the embodiments or in the description of the related art are briefly described below. Obviously, the drawings described below are only some embodiments of the present disclosure, and for those ordinary skilled in the art, other drawings may be obtained based on these drawings without creative efforts.

FIG. 1 is a partial side view of an LED lamp panel according to a first embodiment of the present disclosure.

FIG. 2 is a schematic diagram of a light conduction path of the LED lamp panel according to the first embodiment of the present disclosure.

FIG. 3 is a top view of the LED lamp panel according to a second embodiment of the present disclosure.

FIG. 4 is a top view of the LED lamp panel according to a third embodiment of the present disclosure.

FIG. 5 is a top view of the LED lamp panel according to a fourth embodiment of the present disclosure.

FIG. 6 is a block diagram of a backlight module according to a fifth embodiment of the present disclosure.

### REFERENCE NUMERALS AND DENOTATIONS THEREOF

100—LED lamp panel;
1—base plate; 2—light-emitting chip; 3—sealant layer; 4—optical lens structure; 5—reflecting layer; and
41—concave pit; 42—enclosure; and 51—position avoidance hole.

### DETAILED DESCRIPTION

In order to make the objectives, technical solutions and advantages of the present disclosure more obvious, the present disclosure is further described in detail below in combination with the accompanying drawings and embodiments. It is to be understood that the specific embodiment is intended merely to explain the present disclosure, rather than limiting the present disclosure.

It is to be noted that when an element is described as “fixed to” another element, it may be directly mounted on the element or may involve a centered element present simultaneously. When an element is considered to be “connected” to another element, it may be directly connected to the element or a centered element may be present at the same time. The terms “vertical”, “horizontal”, “left”, “right” and similar expressions used in this article are only for illustrative purposes.

In the description of the present disclosure, it is to be understood that the orientation or state relations indicated by the terms “upper”, “lower”, “left”, “right”, “front”, “rear”, “top”, “bottom”, “inner”, “outer”, “vertical”, “horizontal”, “center”, etc., are based on those shown in the accompanying drawings. These terms are merely for the ease of describing the present disclosure and the embodiments, rather than limiting that the device, element or component referred to must be in a specific orientation or constructed and operated in a specific orientation.

Moreover, some of the above terms may express other meanings in addition to orientation or state relations. For example, the term “upper” may be interpreted as indicating an attachment relationship or connection relationship under some circumstances. For those of ordinary skilled in the art, the specific meanings of the above terms in the present disclosure can be understood according to specific circumstances.

In addition, the terms “mounted”, “arranged”, “disposed”, “connection” and “be connected to” are to be understood in a broad sense. For example, the connection can be fixed connection, detachable connection, integral connection, mechanical connection, electrical connection, direct connection, indirect connection through an intermediate medium, or internal connection between two devices, elements or components. For those of ordinary skilled in the art, the specific meanings of the above terms in the present disclosure can be understood according to specific circumstances.

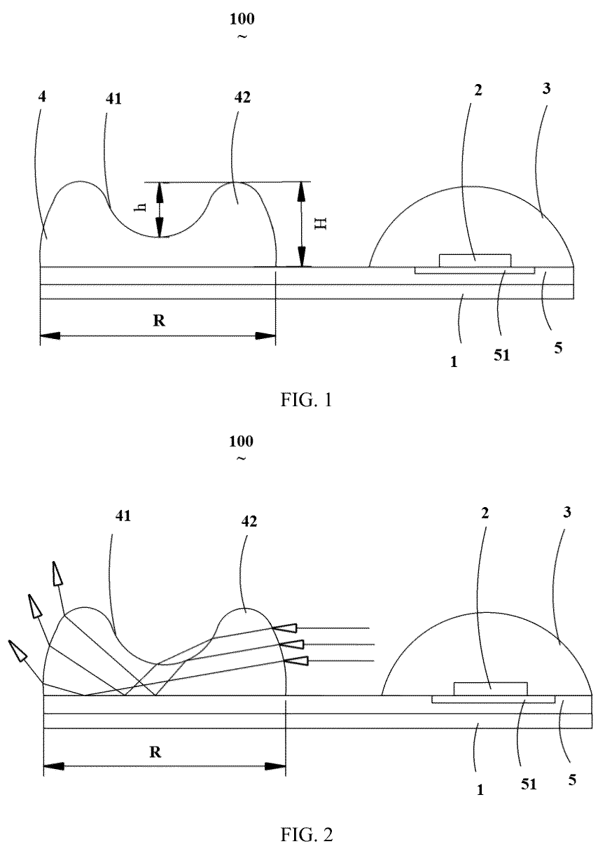

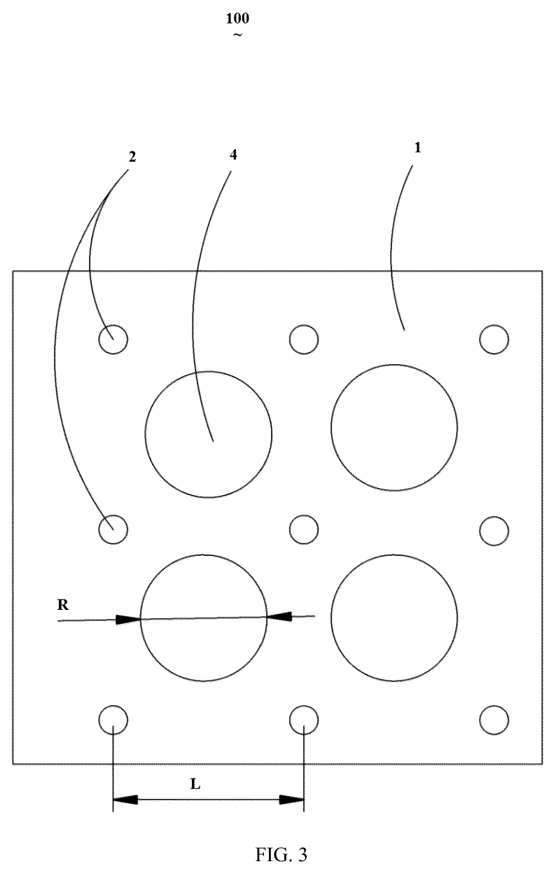

Referring to FIGS. 1-2, an LED lamp panel 100 includes a base plate 1, light-emitting chips 2 are electrically connected to the base plate 1, the light-emitting chips 3 are wrapped with sealant layers 3, and corresponding optical lens structures 4 are arranged between the light-emitting chips 2.

Specifically, the sealant layers 3 are made of transparent optical materials, serving to protect and fix the light-emitting chips 2. The sealant layers 3 can function as a moisture barrier while exhibiting certain optical refractive properties. When light rays traverses through the sealant layers 3, propagation directions undergo controlled deflection, thereby ensuring optimized light focusing or diffusion performance.

Specifically, within the optical lens structures 4, the light rays emitted laterally on the optical lens structures 4 undergo optical processing including refraction, reflection, total internal reflection, etc.

Preferably, light conduction paths of lateral light rays refracted into the optical lens structures 4 are schematically represented in FIG. 2. The optical lens structures 4 with such configuration can conduct the lateral light direction to the other side of the base plate 1, thereby achieving light homogenization.

In a further description, a concave pit 41 is arranged on one face of each optical lens structure 4 away from the base plate 1, and an enclosure 42 is formed around the concave pit 41.

Specifically, the concave pit 41 on the optical lens structure 4 is formed through a dispensing process, creating varying angular inclinations between the concave pit 41 and the enclosure 42. These angular inclinations provide refractive or reflective angles for collimated light rays emitted into the optical lens structure 4, thereby ensuring precise redirection of light rays parallel to the base plate 1 toward a region above the base plate 1.

It is to be understood that the concave pit 41 introduces additional reflective or refractive processes for light rays entering the optical lens structure 4, redirecting collimated incident rays toward the region above base plate 1, and its specific shapes may adopt various shapes such as bowl-type, inverted triangular, or cuboid configurations. In the present disclosure, no specific limitation is imposed on the geometric configurations, only achieving the redirection of light rays parallel to the base plate 1 toward the region above the base plate 1. In this embodiment, the concave pit 41 adopts a bowl-type configuration as illustrated in FIG. 1.

Specifically, a ratio of a bottom height of the concave pit 4 to a diameter of the optical lens structure 4 is less than or equal to 0.6, and a ratio of a maximum height of the enclosure 42 to the diameter of the optical lens structure 4 is less than or equal to 0.8.

In one implementable solution, the bottom height h of the concave pit 4 (denoted as h in FIG. 1) ranges from 1 mm to 2 mm, and the diameter R of the optical lens structure 4 (denoted as R in FIG. 1) ranges from 3 mm to 4 mm. The maximum height H of the enclosure 42 (denoted as H in FIG. 1) is maintained between 1 mm and 2 mm. The ratios of the bottom height h of the concave pit 4 to the diameter R of the optical lens structure 4, and the maximum height H of the enclosure 42 to the diameter R of the optical lens structure 4 are optimized within optimal ranges, thereby ensuring precise control over light distribution and illumination coverage within the optical lens structure 4.

It is to be understood that referring to FIG. 2, incident light rays entering the concave pit 41 undergo reflection or refraction induced by a height differential between the bottom and the enclosure 42, thereby increasing light propagation paths within the optical lens structure 4, concentrating the light rays toward the region above the optical lens structure 4 while enhancing light homogenization efficacy. A greater height differential can concentrate the light rays toward a specific region, whereas a reduced height differential can achieve broadened illumination coverage, thereby accommodating diverse lighting requirements.

In a further description, a minimum height of the concave pit 41 is greater than a height of the light-emitting chip 2 on the base plate 1.

In a further description, a reflecting layer 5 is arranged on the base plate 1, and the optical lens structures 4 and the light-emitting chips 2 are arranged on the reflecting layer 5.

It is to be understood that the reflecting layer 5 can redirect the lateral light rays propagating within the optical lens structure 4 to exteriors of the optical lens structure 4, altering directions of the lateral light rays to achieve more uniform distribution of light rays emitted by the light-emitting chip 2 across one side of the base plate 1, enhancing light utilization efficiency, thereby improving the overall light emission quality of the LED lamp panel 100.

Specifically, in this embodiment, the reflecting layer 5 is a reflecting paper, and this design can allow the LED lamp panel 100 to reduce its overall size.

Specifically, in this embodiment, the base plate 1, the reflecting layer 5 and the light-emitting chips 2 are arranged in layers. The light-emitting chips 2 are arranged on the base plate 1 and is exposed through the reflecting layer 5.

Referring to FIG. 1 again, position avoidance holes 51 corresponding to the light-emitting chips 2 are disposed on the reflecting layer 5. It is to be understood that the position avoidance holes 51 can accommodate the light-emitting chips 2, preventing the reflecting layer 5 from obstructing the light output of the light-emitting chips 2.

Alternatively, the position avoidance holes 51 may be circular or square or other shapes. Specifically, in this embodiment, the position avoidance holes 51 are circular in shape, with centers aligned with central areas of the light-emitting chips 2.

In a further description, each position avoidance hole 51 has an area greater than a projected area of the light-emitting chip 2, further preventing the reflecting layer 5 from obstructing the light output of the light-emitting chips 2.

In a further description, the optical lens structure 4 includes a reflective adhesive, which is transparent adhesive and/or white adhesive.

It is to be understood that the reflecting adhesive can effectively enhance the light homogenization capability of the optical lens structure 4, further forming the optical lens structure 4 through single or multiple coating processes using one or more types of reflecting adhesives.

In a further description, the light-emitting chips 2 may emit monochromatic light or polychromatic light.

Alternatively, a light color of the reflective adhesive may be matched to or differentiated from that of the light-emitting chips 2. Specifically, in this embodiment, the light color of the reflective adhesive is matched to that of the light-emitting chips 2.

In a further description, gaps are arranged between the optical lens structures 4 and the sealant layers 3.

Specifically, widths of the gaps are determined by optical performance requirements, with larger illumination areas requiring improvement correlating to increased diameter of the optical lens structure 4, thereby leading to smaller gaps between the optical lens structures 4 and the sealant layers 3. The gaps can avoid localized compression between the sealant layers 3 and the optical lens structures 4 while preventing heat concentration between the sealant layers 3 and the optical lens structures 4.

In a further description, a ratio of the diameter R of the optical lens structure 4 to a distance L between the two light-emitting chips 2 is greater than or equal to 0.1.

Specifically, referring to FIG. 3, in LED panels 100 of varying sizes, the diameter R of the optical lens structure 4 (denoted as R in FIG. 3) increases proportionally with the increase of the distance L between the two light-emitting chips 2 (denoted as L in FIG. 3). That is, when the size of the LED panel 100 increases, the diameter R of the optical lens structure 4 (denoted as R in FIG. 3) increases accordingly. Furthermore, in the present disclosure, the distance L between the two light-emitting chips 2 is not specifically limited, provided that the optical performance requirements are met.

It is to be understood that a larger-diameter optical lens structure 4 can cover a broader area, capture more lateral light rays, and focus or redirect the rays towards the region directly above the base plate 1, thereby enhancing optical efficiency.

In a further description, the light-emitting chips 2 are arranged in an array on the base plate 1, and the optical lens structures 4 are arranged at centers of a plurality of light-emitting 2.

Referring to FIG. 3, a second embodiment of the present disclosure further provides another LED lamp panel 100, and the light-emitting chips 2 are arranged in an array on the base plate 1.

Preferably, each optical lens structure 4 is arranged at an intersection center of four light-emitting chips 2, and the optical lens structures 4 are distributed in a dot pattern.

It is to be understood that dark zones or bright spots tend to be formed at the intersection center of the four light-emitting chips 2 compared with a region directly above the light-emitting chip 2. The optical lens structure 4 is arranged at the intersection center of the four light-emitting chips 2 in a dot pattern, reflecting the laterally emitted light rays from the four light-emitting chips 2 towards a region directly above the base plate 1, thereby achieving uniform light mixing.

Preferably, in one implementable solution, as illustrated in FIG. 3, the optical lens structure 4 has a diameter R of 3.5 mm, with the enclosure 42 reaching a maximum height H of 1.1 mm. It is arranged at the intersection center of the four light-emitting chip 2, in which a distance between each pair of adjacent light-emitting chip 2 is 7.5 mm. Within the optical lens structure 4, light rays emitted laterally from the four light-emitting chips 2 undergo optical processing including refraction, reflection, and total internal reflection, and are guided toward the region directly above the base plate 1, causing a light-mixing distance to be reduced from an original 3 mm to below 1.5 mm for the same panel size, thereby minimizing light loss and scattering while improving the transmission efficiency of the optical system.

Specifically, if the intersection center of the four light-emitting chips 2 appears darker, a larger light-guiding area is required. Accordingly, the diameter of the optical lens structure 4 is also increased to direct more lateral light rays towards the region directly above the base plate 1.

In a further description, the optical lens structures 4 are arranged between two rows of light-emitting chips 2 and/or between two columns of light-emitting chips 2.

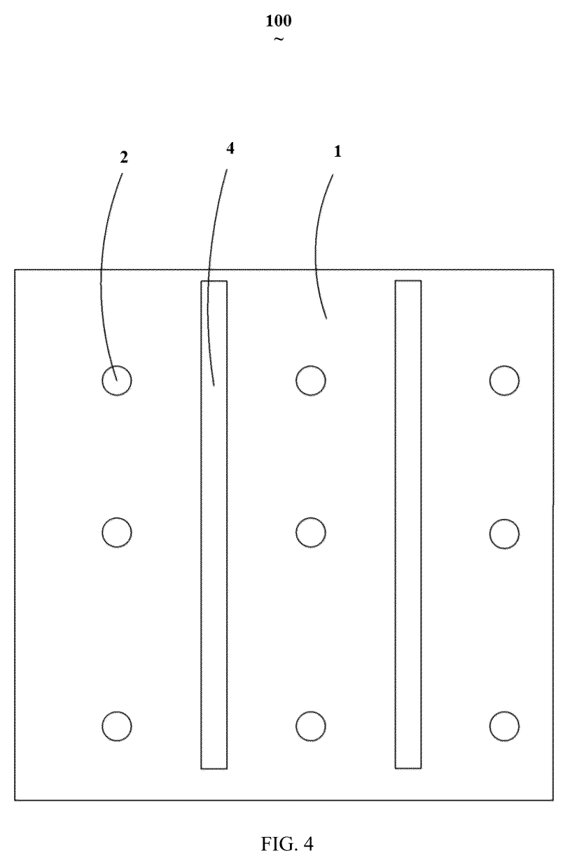

Referring to FIG. 4, a third embodiment of the present disclosure further provides another LED lamp panel 100, and the optical lens structures 4 are distributed in a line pattern.

Alternatively, the optical lens structures 4 may be arranged in linear and/or curved configurations. Specifically, in this embodiment, the optical lens structures 4 are arranged in a linear configuration.

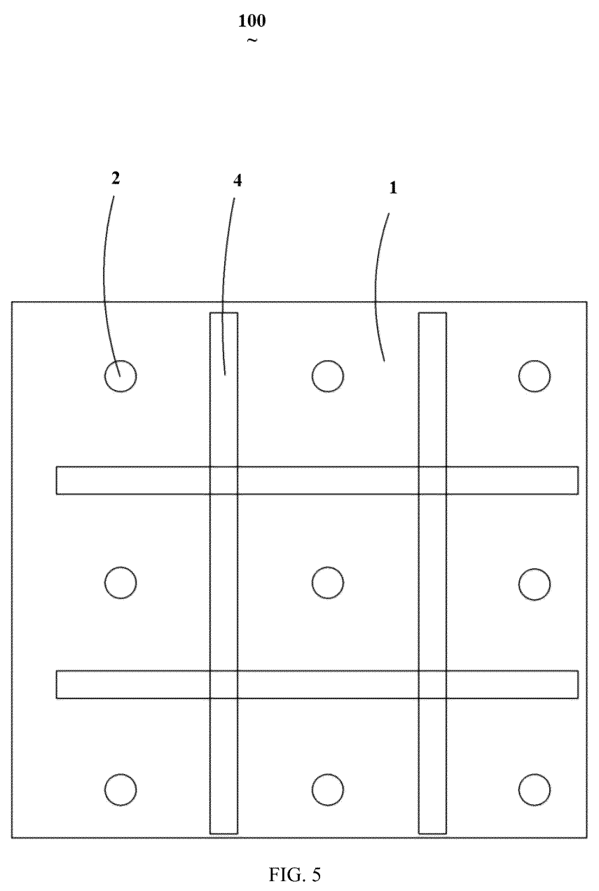

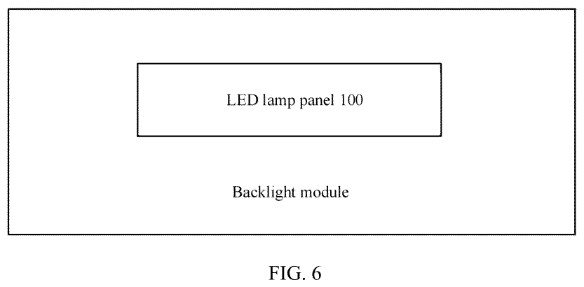

Referring to FIG. 5, a fourth embodiment of the present disclosure further provides another LED lamp panel 100. As an embodiment of deformation, in this embodiment, the optical lens structures 4 are distributed in a mesh pattern.

It is to be understood that when the optical lens structures 4 are arranged between adjacent rows of light-emitting chips 2 and between adjacent columns of light-emitting chips 2, the optical lens structures 4 collectively form a mesh pattern.

Referring to FIG. 5, a fifth embodiment of the present disclosure further provides a backlight module including the above LED lamp panel 100, which has the same beneficial effects as the LED lamp panel 100, thereby obviating the need for redundant detailed description herein.

Compared to the related art, the LED lamp panel and the backlight module provided by the present disclosure have the following advantages.

1. According to the LED lamp panel provided in an embodiment of the present disclosure, the optical lens structures are arranged on the base plate corresponding to the light-emitting chips. Within the optical lens structures, light rays undergo optical processing including refraction, reflection, total internal reflection, etc. The concave pit is arranged on one face of each optical lens structure away from the base plate, and an enclosure is formed around the concave pit, and an enclosure is formed around the concave pit, to cause the light rays to undergo multiple reflections and refractions when passing through the optical lens structures, thereby achieving more uniform coverage across the entire emission area, mitigating observable light spots or non-uniformity, enhancing utilization efficiency of the light-emitting chips, and reducing optical energy loss. Moreover, a reasonably designed optical lens structure can compensate for light rays directed toward one side of the base plate, ensuring more uniform illumination distribution across targeted light areas while enhancing visual performance and ocular comfort.

2. According to the LED lamp panel provided in an embodiment of the present disclosure, the reflecting layer can effectively redirect the lights emitted from the light-emitting chips and the optical lens structures toward an exterior of the base plate, thereby enhancing the overall light output quality of the lamp panel.

3. According to the LED lamp panel provided in an embodiment of the present disclosure, the light-emitting chips are arranged in an array on the base plate, and the optical lens structures are arranged between or around the light-emitting chips. The light rays passing through these optical lens structures are more effectively controlled and directed, facilitating efficient focusing, scattering, or reflection of the emitted light rays from the light-emitting chips.

4. According to the LED lamp panel provided in an embodiment of the present disclosure, various optical lens structure distribution patterns such as dot, line, or mesh patterns, exhibit distinct advantages in LED lamp panels under different emission conditions. Dot-patterned optical lens structures are suitable for use at an intersection center of four lamps, ensuring precise control over light direction. Line-patterned optical lens structures are optimally implemented on LED lamp panels exhibiting stripe-pattern luminance variations. Mesh-patterned optical lens structures can integrate the advantages of both dot and line patterns, ensuring precise control over light directionality and intensity, while facilitating light diffusion and uniform distribution.

5. According to the LED lamp panel provided in an embodiment of the present disclosure, the gaps can provide passages for heat transfer, facilitating the effective dissipation of heat generated by the light-emitting chips into the ambient environment, minimizing direct contact between the optical lens structures and the sealant layers, thereby preventing potential the optical lens structures from being affected by the sealant layers.

6. According to the LED lamp panel provided in an embodiment of the present disclosure, as the distance between the light-emitting chips increases, the diameter of the optical lens structure proportionally enlarges, which enhances optical efficiency by capturing more lateral light rays, thereby expanding illumination coverage while mitigating uneven lighting distribution or optical failures between the optical lens structure and the light-emitting chip.

7. The backlight module provided in an embodiment of the present disclosure has the same beneficial effects as the above LED lamp panel.

The foregoing is only the preferred embodiment of the present disclosure, rather than limiting the present disclosure. Any modification, equivalent substitution, improvement and the like made within the principle of the present disclosure all fall within the scope of protection of the present disclosure.

1. A light emitting diode (LED) lamp panel, comprising a base plate, wherein light-emitting chips are electrically connected to the base plate, the light-emitting chips are wrapped with sealant layers, corresponding optical lens structures are arranged between the light-emitting chips, a concave pit is arranged on one face of each optical lens structure away from the base plate, and an enclosure is formed around the concave pit.

2. The LED lamp panel according to claim 1, wherein a ratio of a bottom height of the concave pit to a diameter of the optical lens structure is less than or equal to 0.6, and a ratio of a maximum height of the enclosure to the diameter of the optical lens structure is less than or equal to 0.8.

3. The LED lamp panel according to claim 1, wherein a reflecting layer is arranged on the base plate, and the optical lens structures and the light-emitting chips are arranged on the reflecting layer.

4. The LED lamp panel according to claim 3, wherein position avoidance holes corresponding to the light-emitting chips are disposed on the reflecting layer.

5. The LED lamp panel according to claim 1, wherein the light-emitting chips are arranged in an array on the base plate, and the optical lens structures are arranged at centers of a plurality of light-emitting chips.

6. The LED lamp panel according to claim 1, wherein the optical lens structures are distributed in dot, line or mesh patterns.

7. The LED lamp panel according to claim 1, wherein gaps are arranged between the optical lens structures and the sealant layers.

8. The LED lamp panel according to claim 1, wherein a ratio of the diameter of the optical lens structure to a distance between the two light-emitting chips is greater than or equal to 0.1.

9. The LED lamp panel according to claim 1, wherein the light-emitting chips may emit monochromatic light or polychromatic light.

10. A backlight module, comprising the LED lamp panel according to claim 1.

11. A backlight module, comprising the LED lamp panel according to claim 2.

12. A backlight module, comprising the LED lamp panel according to claim 3.

13. A backlight module, comprising the LED lamp panel according to claim 4.

14. A backlight module, comprising the LED lamp panel according to claim 5.

15. A backlight module, comprising the LED lamp panel according to claim 6.

16. A backlight module, comprising the LED lamp panel according to claim 7.

17. A backlight module, comprising the LED lamp panel according to claim 8.

18. A backlight module, comprising the LED lamp panel according to claim 9.
